(19) United States
(12) Patent Application Publication
(10) Pub. No.: US 2025/0268066 A1
(43) Pub. Date: Aug. 21, 2025

(54) COVER LAYER FOR DISPLAY DEVICE AND DISPLAY DEVICE COMPRISING COVER LAYER

(71) Applicant: Samsung Display Co., LTD., Yongin-si (KR)

(72) Inventor: Jong Hwan CHO, Yongin-si (KR)

(21) Appl. No.: 18/893,556

(22) Filed: Sep. 23, 2024

(30) Foreign Application Priority Data
Feb. 16, 2024 (KR) 10-2024-0022650

(51) Int. Cl. H10K 59/80; C08J 7/04; C09D 5/33; C09D 183/08; H10K 102/00

(52) U.S. Cl. CPC H10K 59/873; C08J 7/042; C09D 5/004; C09D 183/08; H10K 59/8791; C08J 2367/02; C08J 2483/08; H10K 2102/311

(57) ABSTRACT

According to an embodiment of the disclosure, a cover layer for a display device and a display device including the cover layer are provided. The cover layer includes a first layer that forms a base, a second layer on the first layer and including a random silsesquioxane including an ether functional group, and a third layer on the second layer and including a random silsesquioxane including a perfluoroalkyl functional group.

### CROSS-REFERENCE TO RELATED APPLICATION

The present application claims priority to and the benefit of Korean Patent Application No. 10-2024-0022650, filed on Feb. 16, 2024, in the Korean Intellectual Property Office, the entire content of which is hereby incorporated by reference.

### BACKGROUND

### 1. Field

Embodiments of the disclosure relate to a cover layer for a display device and a display device comprising the cover layer.

### 2. Description of the Related Art

As information technology develops, the importance of a display device, which is a connection medium between a user and information, is increasing.

The display device utilizes a structure to improve external visibility. For example, adjusting external light reflectance for improving external visibility is useful.

The display device may be applicable to various suitable product groups. Accordingly, it is beneficial for the display device to have an excellent property in various physical properties such as flexibility.

### SUMMARY

An aspect of embodiments of the disclosure is to provide a cover layer having improved visibility by controlling external light reflectance and a display device comprising the cover layer.

An aspect of embodiments of the disclosure is to provide a cover layer having an excellent mechanical property and flexibility and a display device comprising the cover layer.

According to an embodiment of the disclosure, a cover layer for a display device may include a first layer that forms a base, a second layer on the first layer and including random silsesquioxane (e.g., silsesquioxane having a random structure) including an ether functional group, and a third layer on the second layer and including random silsesquioxane (e.g., silsesquioxane having a random structure) including a perfluoroalkyl functional group.

According to an embodiment, the first layer may include poly(ethylene terephthalate) (PET).

According to an embodiment, the ether functional group of the second layer may include an ethyl-methyl-ether group, an ether group including 5 carbon atoms, and/or an ether group including 4 carbon atoms.

According to an embodiment, the perfluoroalkyl functional group of the third layer may include CF₂CF₂CF₂CF₃, CF₂CF₂CF₃, and/or CF₂CF₂CF₂CF₂CF₃.

According to an embodiment, the first layer may have a thickness in a range of 30 μm to 95 μm.

According to an embodiment, the second layer may have a thickness in a range of 1 μm to 10 μm.

According to an embodiment, the third layer may have a thickness in a range of 50 nm to 150 nm.

According to an embodiment, a surface of the second layer may contact (e.g., physically contact) the first layer. Another surface of the second layer may contact (e.g., physically contact) the third layer.

According to an embodiment, the cover layer may have a reflectance of 1.4% to 1.6% with respect to light having a wavelength of 550 nm.

According to an embodiment, the third layer may have a refractive index of a range of 1.2 to 1.59.

According to an embodiment, the cover layer may have an elongation of 10% to 15%.

According to an embodiment of the disclosure, a display device may include a light-emitting-element layer including a light emitting element that emits light, and a cover layer on the light-emitting-element layer. The cover layer may include a first layer that forms a base, a second layer on the first layer and including random silsesquioxane (e.g., silsesquioxane having a random structure) including an ether functional group, and a third layer on the second layer and including random silsesquioxane (e.g., silsesquioxane having a random structure) including a perfluoroalkyl functional group.

According to an embodiment, the first layer includes poly (ethylene terephthalate) (PET). The ether functional group of the second layer may include an ethyl-methyl-ether group (C₂H₅OCH₃), an ether group including 5 carbon atoms (C₅OH₁₁), and/or an ether group including 4 carbon atoms (C₄OH₉). The perfluoroalkyl functional group of the third layer may include CF₂CF₂CF₂CF₃, CF₂CF₂CF₃, and/or CF₂CF₂CF₂CF₂CF₃.

According to an embodiment, the first layer may have a thickness in a range of 30 μm to 95 μm. The second layer may have a thickness in a range of 1 μm to 10 μm. The third layer may have a thickness in a range of 50 nm to 150 nm.

According to an embodiment, the third layer may be an uppermost layer of the display device.

According to an embodiment, the display device may be a flexible display device.

According to an embodiment of the disclosure, a cover layer having improved visibility by controlling external light reflectance and a display device comprising the cover layer may be provided.

According to an embodiment of the disclosure, a cover layer having an excellent mechanical property and flexibility and a display device comprising the cover layer may be provided.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a schematic plan view illustrating a display device according to an embodiment;

FIG. 2 is a schematic cross-sectional view illustrating a display device according to an embodiment;

FIG. 3 is a schematic cross-sectional view illustrating a cover layer according to an embodiment;

FIG. 4 is a chemical formula illustrating a material included in a second layer; and

FIG. 5 is a chemical formula illustrating a material included in a third layer.

### DETAILED DESCRIPTION

The subject matter of the disclosure may be modified in various suitable manners and have various suitable forms. Therefore, example embodiments will be illustrated in the drawings and will be described in more detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, and/or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In embodiments, a case where a portion of a layer, a layer, an area, a plate, and/or the like is referred to as being “on” another portion, it includes not only a case where the portion is “directly on” another portion, but also a case where there is further another portion between the portion and the other portion. In the present specification, when a portion of a layer, a layer, an area, a plate, and/or the like is formed on another portion, a forming direction is not limited to an upper direction but includes forming the portion on a side surface and/or in a lower direction. When a portion of a layer, a layer, an area, a plate, or the like is formed “under” another portion, this includes not only a case where the portion is “directly beneath” another portion but also a case where there is further another portion between the portion and the other portion.

The disclosure relates to a cover layer for a display device and a display device comprising the cover layer. Hereinafter, a cover layer for a display device and a display device comprising the cover layer according to an embodiment is described with reference to the accompanying drawings.

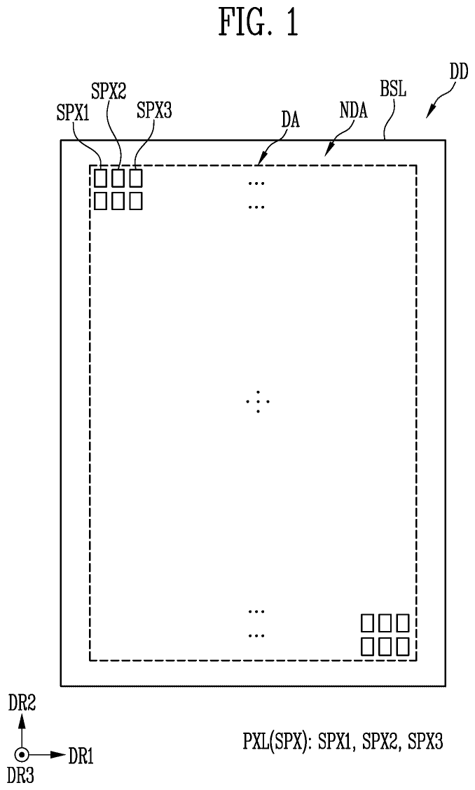

FIG. 1 is a schematic plan view illustrating a display device according to an embodiment.

Referring to FIG. 1, the display device DD may include a base layer BSL and a pixel PXL on the base layer BSL. In embodiments, the display device DD may further include a driving circuit unit (for example, a scan driver and/or a data driver), lines, and pads for driving the pixel PXL.

The display device DD (or the base layer BSL) may include a display area DA and a non-display area NDA. The non-display area NDA may mean an area other than the display area DA. The non-display area NDA may surround at least a portion of the display area DA.

According to an embodiment, the display device DD may be a flexible display device. For example, the display device DD may be a bendable display device, a rollable display device, and/or a foldable display device.

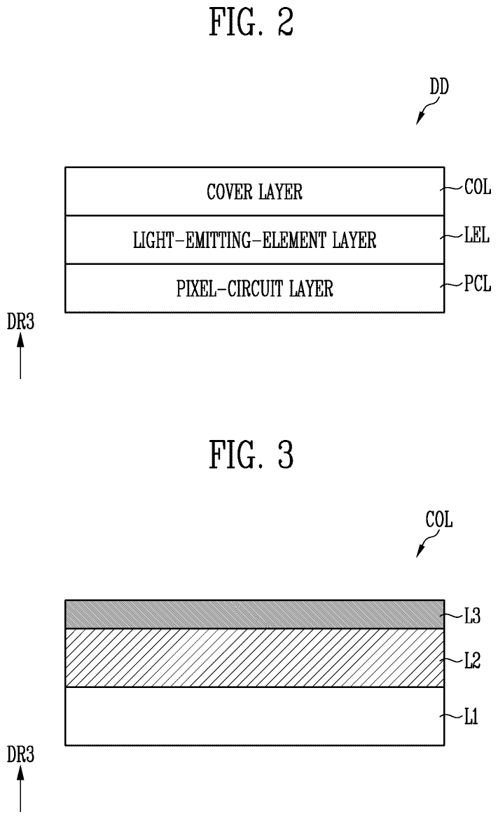

According to an embodiment, the display device DD may include a cover layer COL (refer to FIG. 2) having an excellent mechanical property and flexibility, and thus the display device DD may be suitably applied to a flexible display device.

The base layer BSL may form a base surface of the display device DD. The base layer BSL may be a rigid or flexible substrate and/or film. For example, the base layer BSL may be a rigid substrate formed of glass and/or tempered glass, a flexible substrate (or a thin film) of a plastic and/or metal material, and/or at least one layer of an insulating layer (e.g., an electrically insulating layer). A material and/or a physical property of the base layer BSL are/is not particularly limited. In an embodiment, the base layer BSL may be substantially transparent. Here, substantially transparent may mean that light (e.g., visible light) may be transmitted at one transmittance or more (e.g., at a set transmittance or more). In another embodiment, the base layer BSL may be translucent or opaque. In embodiments, the base layer BSL may include a reflective material according to an embodiment.

The display area DA may be an area where the pixel PXL is provided. The non-display area NDA may be an area where the pixel PXL is not provided. The driving circuit unit, the line, and the pads connected to the pixel PXL of the display area DA may be in the non-display area NDA.

According to an embodiment, the pixel PXL (or sub-pixels SPX) may be arranged according to a stripe or PENTILE® arrangement structure (e.g., an RGBG matrix, RGBG structure, or RGBG matrix structure), but are not limited thereto, and various suitable embodiments may be in the scope of the disclosure. PENTILE® is a duly registered trademark of Samsung Display Co., Ltd.

According to an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one selected from the first sub-pixel SPX1, the second sub-pixel SPX2, and the third sub-pixel SPX3 may form a pixel unit configured to emit light of various suitable colors.

For example, each of the first sub-pixel SPX1, the second sub-pixel SPX2, and the third sub-pixel SPX3 may emit light of a color (e.g., a set color). For example, the first sub-pixel SPX1 may be a red pixel that emits red light (for example, a first color), the second sub-pixel SPX2 may be a green pixel that emits green light (for example, a second color), and the third sub-pixel SPX3 may be a blue pixel that emits blue light (for example, a third color). According to an embodiment, the number of second sub-pixels SPX2 may be greater than the number of first sub-pixels SPX1 and the number of third sub-pixels SPX3. However, the color, type (or kind), number, and/or the like of the first sub-pixel SPX1, the second sub-pixel SPX2, and the third sub-pixel SPX3 that form each pixel unit are/is not limited to a specific example.

FIG. 2 is a schematic cross-sectional view illustrating a display device according to an embodiment.

Referring to FIG. 2, the display device DD may include a pixel-circuit layer PCL (for example, a backplane layer), a light-emitting-element layer LEL, and a cover layer COL.

The pixel-circuit layer PCL may be a layer including a pixel circuit that drives the pixel PXL (or a light emitting element included in the light-emitting-element layer LEL) formed by the light-emitting-element layer LEL. The pixel-circuit layer PCL may include a base layer BSL, conductive layers (e.g., electrically conductive layers) that form pixel circuits, and insulating layers (e.g., electrically insulating layers) on the conductive layers.

The light-emitting-element layer LEL may be on the pixel-circuit layer PCL. According to an embodiment, the light-emitting-element layer LEL may include the light emitting element. According to an embodiment, the light emitting element may include an organic light emitting diode (OLED). In embodiments, the light emitting element may include an inorganic light emitting element including an inorganic material. In embodiments, the light-emitting-element layer LEL may include a liquid crystal display (LCD). However, the disclosure is not limited thereto.

The cover layer COL may be on the light-emitting-element layer LEL. The cover layer COL may transmit light emitted from the light-emitting-element layer LEL.

Details regarding the cover layer COL according to an embodiment are further described below with reference to FIGS. 3-5.

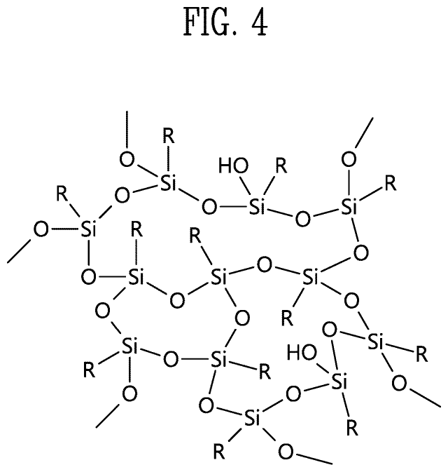

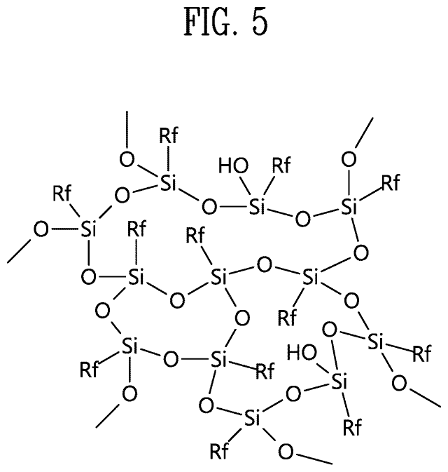

FIG. 3 is a schematic cross-sectional view illustrating a cover layer according to an embodiment. FIG. 4 is a chemical formula illustrating a material included in a second layer. FIG. 5 is a chemical formula illustrating a material included in a third layer.

Referring to FIGS. 3-5, the cover layer COL may include a first layer L1, a second layer L2, and a third layer L3.

The first layer L1 may be a base of the cover layer COL. For example, the first layer L1 may form a base on which the second layer L2 is provided. According to an embodiment, the first layer L1 may be a film-type layer.

The first layer L1 may include an organic material. For example, the first layer L1 may include poly(ethylene terephthalate) (PET). However, the disclosure is not limited thereto.

According to an embodiment, the first layer L1 may have a thickness of 30 μm to 95 μm. For example, the first layer L1 may have a thickness of 65 μm. However, the disclosure is not limited thereto.

According to an embodiment, each of the second layer L2 and the third layer L3 may include random silsesquioxane (e.g., silsesquioxane having a random structure) including different functional groups. Accordingly, the cover layer COL may concurrently (e.g., simultaneously) satisfy various suitable physical properties useful for visibility, a mechanical property, and/or the like of the display device DD.

The random silsesquioxane is one of various suitable structure examples of silsesquioxane. The random silsesquioxane is a siloxane material including Si—O—Si silicon-oxygen-silicon bonding. The random silsesquioxane may be manufactured based on a hydrolysis condensation method of alkoxy and/or chlorosilane. However, the disclosure is not limited thereto.

In the random silsesquioxane, an organic compound and an inorganic compound may form a three-dimensional connection structure. The random silsesquioxane may be an organic-inorganic hybrid material in which the organic compound and the inorganic compound are combined at a molecular scale.

Accordingly, the random silsesquioxane may have a property of an inorganic material and a property of an organic material.

For example, the random silsesquioxane may have relatively excellent flexibility and solubility as properties of the organic material. In embodiments, the random silsesquioxane may have relatively excellent heat resistance and hardness property as properties of the inorganic material.

According to an embodiment, because the random silsesquioxane may have excellent flexibility, the display device DD including the cover layer COL may be applicable to a flexible display device. Accordingly, even though the display device DD is implemented as a flexible display device, a possibility of risk or deterioration in mechanical behavior, such as a crack occurring in the display device DD, may be reduced.

For example, the cover layer COL may have a crack strain of 10% to 15%. According to an embodiment, the cover layer COL may have a crack strain of 12.5%. The crack strain is a physical property that indicates deformation resistance and is the same or substantially the same as elongation. The crack strain of the cover layer COL may be measured using any suitable equipment generally used in the art for measuring elongation.

The second layer L2 may be on the first layer L1. The second layer L2 may be between the first layer L1 and the third layer L3. According to an embodiment, the second layer L2 may be directly on (for example, contact) the first layer L1.

The second layer L2 may include random silsesquioxane (e.g., silsesquioxane having a random structure) including an ether functional group. A chemical formula of the random silsesquioxane including the ether functional group is shown in FIG. 4. In FIG. 4, R may represent the ether group (for example, CₙOH₂ₙ₊₁).

For example, R may represent an ethyl-methyl-ether group (C₂H₄OCH₃ or C₂H₅OCH₂). In embodiments, R may represent an ether group including 5 carbon atoms (C₅OH₁₁). In embodiments, R may represent an ether group including four carbon atoms (C₄OH₉).

The random silsesquioxane including the ethyl-methyl-ether functional group according to an embodiment may include 12 ethyl-methyl-ether groups in a molecule. The random silsesquioxane including the ethyl-methyl-ether functional group may include six reactive groups.

According to an embodiment, the second layer L2 may be a hard coating layer. For example, the second layer L2 may have high hardness as it includes the random silsesquioxane including the ethyl-methyl-ether group, and may have relatively excellent flexibility. In embodiments, as the second layer L2 includes the random silsesquioxane having an excellent mechanical property, stretchability and wear resistance of the cover layer COL may be improved.

According to an embodiment, as the second layer L2 includes the random silsesquioxane including the ethyl-methyl-ether functional group, the second layer L2 may have excellent heat resistance.

According to an embodiment, the second layer L2 may be manufactured by depositing the random silsesquioxane that forms the second layer L2 on the first layer L1. Because reactivity of the random silsesquioxane is excellent, the second layer L2 may be efficiently manufactured through a vacuum deposition polymerization process.

According to an embodiment, the second layer L2 may have a thickness in a range of 1 μm to 10 μm. For example, the second layer L2 may have a thickness in 5 μm.

The third layer L3 may be on the second layer L2. The third layer L3 may be the uppermost layer of the cover layer COL. The third layer L3 may be the uppermost layer of the display device DD. According to an embodiment, the third layer L3 may be directly on (for example, contact) the second layer L2.

The third layer L3 may include random silsesquioxane (e.g., silsesquioxane having a random structure) including a perfluoroalkyl functional group. A chemical formula of the random silsesquioxane including the perfluoroalkyl functional group is shown in FIG. 5. In FIG. 5, Rf may represent a fluorine-based perfluoroalkyl functional group (for example, CₙF₂ₙ₊₁). For example, Rf may include a fluorine-based perfluoroalkyl functional group including four carbon atoms (CF₂CF₂CF₂CF₃). In embodiments, Rf may include a fluorine-based perfluoroalkyl functional group including three carbon atoms (CF₂CF₂CF₃). In embodiments, Rf may include a fluorine-based perfluoroalkyl functional group including five carbon atoms (CF₂CF₂CF₂CF₂CF₃).

The random silsesquioxane including the perfluoroalkyl functional group according to an embodiment may include 12 fluorine-based perfluoroalkyl functional groups in a molecule. The random silsesquioxane including the perfluoroalkyl functional group may include six reactive groups.

According to an embodiment, the third layer L3 may be a low refractive layer. For example, the third layer L3 may have a refractive index lower than that of the second layer L2. According to an embodiment, the refractive index of the third layer L3 may be in a range of 1.2 to 1.59. According to an embodiment, the refractive index of the third layer L3 may be 1.39.

According to an embodiment, the third layer L3 may have a low-reflection property. For example, a reflectance of the cover layer COL including the third layer L3 may be 1.4% to 1.6%. For example, the reflectance of the cover layer COL including the third layer L3 may be 1.42% or 1.51%. In embodiments, the reflectance of the cover layer COL including the third layer L3 may be specified based on an embodiment in which a thickness of the third layer L3 is 100 nm and a wavelength of applied light is 550 nm. However, the disclosure is not limited thereto.

Accordingly, the third layer L3 may implement a low-reflection property for external light, and an external light reflectance for the display device DD may be reduced. Accordingly, a risk that visibility is impaired by external light may be reduced, and a display device DD having improved visibility may be provided. Ultimately, the display device DD according to an embodiment may be provided to have high visibility and be applicable to a flexible display device.

According to an embodiment, the third layer L3 may be an anti-fingerprint layer. According to an embodiment, an upper surface of the third layer L3 may be exposed. The upper surface of the third layer L3 may include an area where a body of the display device DD touches and a touch event may occur. According to an embodiment, the third layer L3 provided relatively at an upper side may include random silsesquioxane (e.g., a fluorine-based material) including the perfluoroalkyl functional group, and thus the third layer L3 may have excellent wear resistance and friction resistance properties and may function as the anti-fingerprint layer. Therefore, an additional layer for implementing the anti-fingerprint layer may not be required, and a process cost may ultimately be reduced.

According to an embodiment, the third layer L3 may be manufactured by depositing the random silsesquioxane that forms the third layer L3 on the second layer L2. As described above, because the reactivity of the random silsesquioxane is excellent, the third layer L3 may be efficiently manufactured through a vacuum deposition polymerization process.

According to an embodiment, the third layer L3 may have a thickness in a range of 50 nm to 150 nm. The third layer L3 may have a thickness in a range of 80 nm to 120 nm. For example, the third layer L3 may have a thickness of 100 nm.

Ultimately, as the display device DD according to an embodiment includes the cover layer COL including the second and third layers L2 and L3 respectively including different random silsesquioxanes, the display device DD having improved display quality and an improved mechanical property, which may be applied to various suitable flexible devices, may be provided.

As described above, although the subject matter of the disclosure has been described with reference to example embodiments above, those skilled in the art or those having ordinary skill in the art will understand that the subject matter of the disclosure may be variously modified and changed without departing from the spirit and technical area of the disclosure described in the appended claims, and equivalents thereof.

Therefore, the technical scope of the disclosure should not be limited to the contents described in the detailed description of the specification, but should be defined by the appended claims, and equivalents thereof.

1. A cover layer for a display device, wherein the cover layer comprises:
a first layer that forms a base;
a second layer on the first layer and comprising a random silsesquioxane comprising an ether functional group; and
a third layer on the second layer and comprising a random silsesquioxane comprising a perfluoroalkyl functional group.

2. The cover layer according to claim 1, wherein the first layer comprises poly(ethylene terephthalate).

3. The cover layer according to claim 1, wherein the ether functional group of the second layer comprises an ethyl-methyl-ether group, an ether group comprising 5 carbon atoms, or an ether group comprising 4 carbon atoms.

4. The cover layer according to claim 1, wherein the perfluoroalkyl functional group of the third layer comprises CF₂CF₂CF₂CF₃, CF₂CF₂CF₃, or CF₂CF₂CF₂CF₂CF₃.

5. The cover layer according to claim 1, wherein the first layer has a thickness in a range of 30 μm to 95 μm.

6. The cover layer according to claim 1, wherein the second layer has a thickness in a range of 1 μm to 10 μm.

7. The cover layer according to claim 1, wherein the third layer has a thickness in a range of 50 nm to 150 nm.

8. The cover layer according to claim 1, wherein a surface of the second layer contacts the first layer, and
another surface of the second layer contacts the third layer.

9. The cover layer according to claim 1, wherein the cover layer has a reflectance of 1.4% to 1.6% with respect to light having a wavelength of 550 nm.

10. The cover layer according to claim 1, wherein the third layer has a refractive index of a range of 1.2 to 1.59.

11. The cover layer according to claim 1, wherein the cover layer has an elongation of 10% to 15%.

12. A display device, wherein the display device comprises:
a light-emitting-element layer comprising a light emitting element that emits light; and
a cover layer on the light-emitting-element layer,
wherein the cover layer comprises:
a first layer that forms a base;
a second layer on the first layer and comprising a random silsesquioxane comprising an ether functional group; and
a third layer on the second layer and comprising a random silsesquioxane comprising a perfluoroalkyl functional group.

13. The display device according to claim 12, wherein the first layer comprises poly(ethylene terephthalate),
The ether functional group of the second layer comprises an ethyl-methyl-ether group, an ether group comprising 5 carbon atoms, or an ether group comprising 4 carbon atoms, and
the perfluoroalkyl functional group of the third layer comprises CF₂CF₂CF₂CF₃, CF₂CF₂CF₃, or CF₂CF₂CF₂CF₂CF₃.

14. The display device according to claim 12, wherein the first layer has a thickness in a range of 30 μm to 95 μm,
The second layer has a thickness in a range of 1 μm to 10 μm, and
the third layer has a thickness in a range of 50 nm to 150 nm.

15. The display device according to claim 12, wherein the third layer is an uppermost layer of the display device.

16. The display device according to claim 12, wherein the display device is a flexible display device.
